(19) United States
(12) Patent Application Publication
(10) Pub. No.: US 2026/0135530 A1
(43) Pub. Date: May 14, 2026

(54) HYBRID DIFFERENTIAL AMPLIFIER WITH HIGH LINEARITY AND METHOD THEREOF

(71) Applicant: Richtek Technology Corporation, Hsinchu (TW)

(72) Inventors: Yi-Kuang CHEN, Hsinchu (TW); Shao-Ming SUN, Hsinchu (TW); Ming-Jun HSIAO, Hsinchu (TW)

(21) Appl. No.: 19/173,860

(22) Filed: Apr. 9, 2025

(30) Foreign Application Priority Data
Nov. 14, 2024 (TW) 113143733

(51) Int. Cl. H03F 3/45; H03F 1/08

(52) U.S. Cl. CPC H03F 3/45475; H03F 1/083; H03F 2203/45662

(57) ABSTRACT

A hybrid differential amplifier generating a differential output signal based on a differential input signal having a fundamental frequency includes: a first amplifier configured as an inductive switching converter; and a second amplifier configured as another type of amplifier. The first and second amplifiers respectively generate first and second output signals of the differential output signal based on first and second input signals of the differential input signal. One of the first or second amplifiers further generates the first or second output signal based on feedback, thereby the differential output signal is linearly related to the differential input signal. The other amplifier performs a quantization processing on the first or second input signal, thereby the second output signal includes a staircase wave related to the fundamental frequency. The quantization processing includes generating a quantized output signal based on the first or second input signal and at least one threshold level.

### CROSS REFERENCE

The present invention claims priority to the TW patent application Ser. No. 113143733, filed on Nov. 14, 2024.

### BACKGROUND OF THE INVENTION

### Field of Invention

The present invention relates to a hybrid differential amplifier, and more particularly to a hybrid differential amplifier with high linearity. The present invention also relates to a method for controlling the aforementioned hybrid differential amplifier.

### Description of Related Art

FIG. 1A shows a simplified block diagram of a hybrid differential amplifier of the prior art. The hybrid differential amplifier of the prior art includes a first amplification circuit and a second amplification circuit, configured to respectively amplify a first input signal Vip and a second input signal Vin of a differential input signal, and to generate a corresponding first output signal Vop and second output signal Von. The first amplification circuit is configured as a switching class-D converter, and the second amplification circuit is configured as an analog amplifier. Compared with a conventional pure class-D amplifier, the prior art design eliminates one LC filter. However, since the second amplification circuit is implemented as an analog amplifier, the overall conversion efficiency and linearity of the differential amplifier are degraded.

FIG. 1B shows a waveform diagram of the operation of the hybrid differential amplifier of the prior art. As shown in FIG. 1B, the drawbacks of the prior art include: due to a delay time Td between the first output signal Vop and the second output signal Von, the first output signal Vop may exceed a lower limit LML or an upper limit LMU of the supply voltage and enter into a saturation state, resulting in nonlinear distortion in the first output signal Vop and the differential output signal Vod. This is shown at the intersection point between the differential output signal Vod and a second output signal Von′, wherein the second output signal Von′ represents the waveform of the second output signal Von aligned in the same time domain as the differential output signal Vod.

In view of the above, to overcome the drawbacks in the prior art, the present invention provides a hybrid differential amplifier with high linearity. Through a quantization processing operation performed by either the first amplifier or the second amplifier, the second output signal Von includes a staircase wave, which has three levels. A duration of a middle level among the three levels is longer than a delay time between the first output signal Vop and the second output signal Von, thereby generating a differential output signal with high linearity.

### SUMMARY OF THE INVENTION

From one perspective, the present invention provides a hybrid differential amplifier, configured to generate a differential output signal based on a differential input signal for driving a load, wherein the differential input signal has a fundamental frequency, the hybrid differential amplifier comprising: a first amplifier, configured as an inductive switching converter and configured to perform pulse width modulation (PWM) conversion based on a first input signal of the differential input signal to switch an inductor and generate a first output signal of the differential output signal; and a second amplifier, configured to generate a second output signal of the differential output signal based on a second input signal of the differential input signal; wherein the second amplifier is configured as another type of amplifier different from the inductive switching converter; wherein one of the first amplifier or the second amplifier is further configured to generate the first output signal or the second output signal based on feedback from the differential output signal, such that the differential output signal is linearly related to the differential input signal; wherein the other one of the first amplifier or the second amplifier is further configured to perform a quantization processing operation on the first input signal or the second input signal, such that the second output signal includes a staircase wave related to the fundamental frequency, wherein the staircase wave includes at least three quantized output levels; wherein the quantization processing operation includes: generating a quantized output signal based on the first input signal or the second input signal and at least one quantization threshold level, such that the second output signal includes the staircase wave.

In one embodiment, the at least three quantized output levels include a first staircase level, a second staircase level, and a ground level, wherein the second staircase level is lower than the first staircase level and higher than the ground level, and a duration of the second staircase level is longer than a delay time between the first output signal and the second output signal, such that a distortion level of the differential output signal is less than a predetermined level.

In one embodiment, the first staircase level corresponds to a voltage level of a supply voltage, and the second staircase level corresponds to a divided voltage level of the supply voltage.

In one embodiment, the second amplifier includes: a quantization control circuit, coupled to the second input signal; and a selection circuit, coupled between the quantization control circuit and the second output signal; wherein the quantization processing operation includes: the quantization control circuit being configured to generate a quantization control signal based on the second input signal and the at least one quantization threshold level; and the selection circuit being configured to select the first staircase level, the second staircase level, or the ground level based on the quantization control signal to generate the quantized output signal; wherein the quantized output signal corresponds to the second output signal.

In one embodiment, the first amplifier includes: a loop filter circuit, configured to perform linear integration based on a difference between the differential output signal and the differential input signal to generate a loop filter signal; a PWM circuit, configured to generate a PWM output signal based on a comparison of the loop filter signal and a triangular wave; and a switching power stage circuit, configured to switch the inductor based on the PWM output signal to generate the first output signal; wherein the first amplifier performs feedback control such that the first output signal includes a superposition of the first input signal and the staircase wave.

In one embodiment, the second amplifier is configured as a linear amplifier operating in continuous time domain, and includes: a quantization circuit, coupled to the second input signal; and an amplification stage circuit, coupled between the quantization circuit and the second output signal; wherein the quantization processing operation includes: the quantization circuit being configured to generate the quantized output signal based on the second input signal and the at least one quantization threshold level, wherein the quantized output signal includes a square wave or the staircase wave, each of which are related to the fundamental frequency; and the amplification stage circuit being configured to linearly amplify the quantized output signal to generate the second output signal; wherein the square wave includes two levels corresponding to the first staircase level and the ground level, and the staircase wave includes three levels corresponding to the first staircase level, the second staircase level, and the ground level.

In one embodiment, the first amplifier includes: a loop filter circuit, configured to perform linear integration based on a difference between the differential output signal and the differential input signal to generate a loop filter signal; a PWM circuit, configured to generate a PWM output signal based on a comparison of the loop filter signal and a triangular wave; and a switching power stage circuit, configured to switch the inductor based on the PWM output signal to generate the first output signal; wherein the first amplifier performs feedback control such that the first output signal includes a superposition of the first input signal and the staircase wave.

In one embodiment, when the quantized output signal includes the square wave related to the fundamental frequency, the amplification stage circuit includes: a class-B amplifier including a first high-side transistor and a first low-side transistor, wherein a gate of the first high-side transistor and a gate of the first low-side transistor are coupled to each other and are coupled to the quantized output signal, and the first high-side transistor and the first low-side transistor are connected in series between a supply voltage and a ground potential to generate the second output signal, wherein the duration of the second staircase level is related to a turn-on threshold of the first high-side transistor and a turn-on threshold of the first low-side transistor; or a class-AB amplifier including a second high-side transistor, a second low-side transistor, and a level shifter, wherein a first terminal and a second terminal of the level shifter are respectively coupled to a gate of the second high-side transistor and a gate of the second low-side transistor, to maintain a voltage difference between the gates of the second high-side transistor and the second low-side transistor, and an input terminal of the level shifter is coupled to the quantized output signal to control voltages of the first terminal and the second terminal, wherein the second high-side transistor and the second low-side transistor are connected in series between a supply voltage and a ground potential to generate the second output signal, wherein a duration of the second staircase level is related to a turn-on threshold of the second high-side transistor, a turn-on threshold of the second low-side transistor, and an offset level of the level shifter; wherein the supply voltage has the first staircase level, and the ground potential corresponds to the ground level.

In one embodiment, when the quantized output signal includes the staircase wave related to the fundamental frequency, the amplification stage circuit includes: a class-AB amplifier including a high-side transistor, a low-side transistor, and a level shifter, wherein a first terminal and a second terminal of the level shifter are respectively coupled to a gate of the high-side transistor and a gate of the low-side transistor, to maintain a voltage difference between the gates of the high-side transistor and the low-side transistor, and an input terminal of the level shifter is coupled to the quantized output signal to control voltages of the first terminal and the second terminal, wherein the high-side transistor and the low-side transistor are connected in series between a supply voltage and a ground potential to generate the second output signal, wherein a duration of the second staircase level is related to a turn-on threshold of the high-side transistor, a turn-on threshold of the low-side transistor, and an offset level of the level shifter; wherein the supply voltage has the first staircase level, and the ground potential corresponds to the ground level.

In one embodiment, the first amplifier includes: a pre-processing circuit, configured to perform a pre-processing operation based on the first input signal and/or the second input signal to generate a pre-processed output signal; a PWM circuit, configured to generate a PWM output signal based on a comparison of the pre-processed output signal and a triangular wave; and a switching power stage circuit, configured to switch the inductor based on the PWM output signal to generate the first output signal; wherein the pre-processing operation includes: performing the quantization processing operation based on the first input signal and/or the second input signal and the at least one quantization threshold level to generate the quantized output signal, and superimposing the quantized output signal with the first input signal to generate the pre-processed output signal; wherein the quantized output signal includes the staircase wave, and the staircase wave includes the first staircase level, the second staircase level, and the ground level.

In one embodiment, the second amplifier includes: a loop filter circuit, configured to perform linear integration based on a difference between the differential output signal and the differential input signal to generate a loop filter signal; a gain stage circuit, configured to linearly amplify the loop filter signal to generate a gain output signal; and an amplification stage circuit, configured to linearly amplify the gain output signal to generate the second output signal; wherein the second amplifier performs feedback control such that the second output signal includes the staircase wave.

From another perspective, the present invention provides a hybrid differential amplification method, configured to generate a differential output signal based on a differential input signal for driving a load, wherein the differential input signal has a fundamental frequency, the hybrid differential amplification method comprising: performing pulse width modulation (PWM) conversion based on a first input signal of the differential input signal to generate a first output signal of the differential output signal; and generating a second output signal of the differential output signal based on a second input signal of the differential input signal; wherein the second output signal is generated in a manner different from the PWM conversion; wherein one of the first output signal or the second output signal is further generated based on feedback from the differential output signal, such that the differential output signal is linearly related to the differential input signal; wherein the other one of the first output signal or the second output signal is further generated based on a quantization processing operation of the first input signal or the second input signal, such that the second output signal includes a staircase wave related to the fundamental frequency, wherein the staircase wave includes at least three quantized output levels; wherein the quantization processing operation includes: generating a quantized output signal based on the first input signal or the second input signal and at least one quantization threshold level, such that the second output signal includes the staircase wave.

The objectives, technical details, features, and effects of the present invention will be better understood with regard to the detailed description of the embodiments below, with reference to the attached drawings.

### BRIEF DESCRIPTION OF THE DRAWINGS

FIG. 1A shows a simplified block diagram of a hybrid differential amplifier of the prior art.

FIG. 1B shows a waveform diagram of the operation of the hybrid differential amplifier of the prior art.

FIG. 2A shows a circuit block diagram of the hybrid differential amplifier according to an embodiment of the present invention.

FIG. 2B shows a circuit block diagram of the hybrid differential amplifier according to another embodiment of the present invention.

FIG. 3A and FIG. 3B show circuit block diagrams of the hybrid differential amplifier corresponding to FIG. 2A according to two embodiments of the present invention.

FIG. 4A and FIG. 4B show circuit block diagrams of the second amplifier corresponding to the hybrid differential amplifier shown in FIG. 3A according to two embodiments of the present invention.

FIG. 5 shows a circuit block diagram of the first amplifier corresponding to the hybrid differential amplifier shown in FIG. 2A according to an embodiment of the present invention.

FIG. 6 shows a schematic circuit diagram of the second amplifier corresponding to the hybrid differential amplifier of FIG. 3B according to an embodiment of the present invention.

FIG. 7 shows a waveform diagram of the hybrid differential amplifier according to an embodiment of the present invention.

FIG. 8 to FIG. 11 show schematic circuit diagrams of a second amplifier corresponding to the hybrid differential amplifier shown in FIG. 6 according to plural embodiments of the present invention.

FIG. 12A and FIG. 12B show schematic circuit diagrams of the second amplifier of the hybrid differential amplifier according to two embodiments of the present invention.

FIG. 13 shows a waveform diagram of quantized output signals corresponding to FIGS. 12A and 12B according to two embodiments of the present invention.

FIG. 14 shows a schematic circuit diagram of the second amplifier corresponding to the hybrid differential amplifier of FIG. 12A according to an embodiment of the present invention.

FIG. 15A shows a schematic diagram of an amplification stage circuit corresponding to the second amplifier of FIG. 12B according to a specific embodiment of the present invention.

FIG. 15B shows a schematic diagram of an amplification stage circuit corresponding to the second amplifiers of FIGS. 12A and 12B according to a specific embodiment of the present invention.

FIG. 16 shows a circuit block diagram of the hybrid differential amplifier corresponding to FIG. 2B according to an embodiment of the present invention.

FIG. 17 shows a circuit block diagram of a pre-processing circuit corresponding to the first amplifier of FIG. 16 according to one embodiment of the present invention.

### DESCRIPTION OF THE PREFERRED EMBODIMENTS

The drawings as referred to throughout the description of the present invention are for illustration only, to show the interrelations between the circuits and the signal waveforms, but not drawn according to actual scale of circuit sizes and signal amplitudes and frequencies.

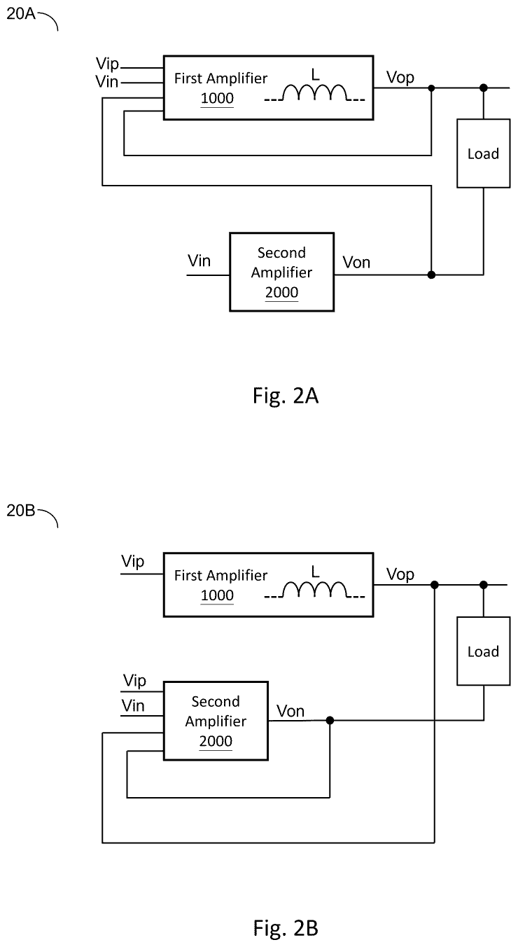

FIG. 2A shows a circuit block diagram of the hybrid differential amplifier according to an embodiment of the present invention. FIG. 2B shows a circuit block diagram of the hybrid differential amplifier according to another embodiment of the present invention. As shown in FIGS. 2A and 2B, a hybrid differential amplifier 20A or 20B of the present invention is configured to generate a differential output signal Vod based on a differential input signal Vid for driving a load, wherein the differential input signal Vid has a fundamental frequency Ff. In one embodiment, each of the hybrid differential amplifier 20A or 20B comprises a first amplifier 1000 and a second amplifier 2000. In one embodiment, the first amplifier 1000 is configured as an inductive switching converter and configured to perform pulse width modulation (PWM) conversion based on a first input signal Vip of the differential input signal Vid to switch an inductor L and generate a first output signal Vop of the differential output signal Vod. In one embodiment, the second amplifier 2000 is configured to generate a second output signal Von of the differential output signal Vod based on a second input signal Vin of the differential input signal Vid. In one embodiment, the second amplifier 2000 is configured as another type of amplifier different from the inductive switching converter. Specifically, in the present embodiment, the first amplifier 1000 is configured as a class-D amplifier, and the second amplifier 2000 may be configured as a class-B amplifier or a class-AB amplifier, which will be described in detail later.

In one embodiment, the first input signal Vip and the first output signal Vop are, for example, a positive input signal and a positive output signal, respectively, and the second input signal Vin and the second output signal Von are, for example, a negative input signal and a negative output signal, respectively, wherein the positive and negative input signals are complementary. In one embodiment, the differential input signal Vid refers to a difference signal between the first input signal Vip and the second input signal Vin, and the differential output signal Vod refers to a difference signal between the first output signal Vop and the second output signal Von.

In one embodiment, one of the first amplifier 1000 or the second amplifier 2000 is further configured to generate the first output signal Vop or the second output signal Von based on feedback from the differential output signal Vod, such that the differential output signal Vod is linearly related to the differential input signal Vid. In one embodiment, the other one of the first amplifier 1000 or the second amplifier 2000 is further configured to perform a quantization processing operation on the first input signal Vip or the second input signal Vin, such that the second output signal Von includes a staircase wave related to the fundamental frequency Ff, wherein the staircase wave includes at least three quantized output levels (described in detail later). In a specific embodiment, as shown in FIG. 2A, the first amplifier 1000 includes a feedback loop, and the second amplifier 2000 is configured to perform the quantization processing operation on the second input signal Vin. In another specific embodiment, as shown in FIG. 2B, the second amplifier 2000 includes a feedback loop, and the first amplifier 1000 is configured to perform a pre-processing operation on the first input signal Vip, wherein the pre-processing operation includes the quantization processing operation in one embodiment. In one embodiment, the quantization processing operation includes generating a quantized output signal based on the first input signal Vip or the second input signal Vin and at least one quantization threshold level, such that the second output signal Von includes the staircase wave, wherein the details of the pre-processing operation and the quantization processing operation will be described later.

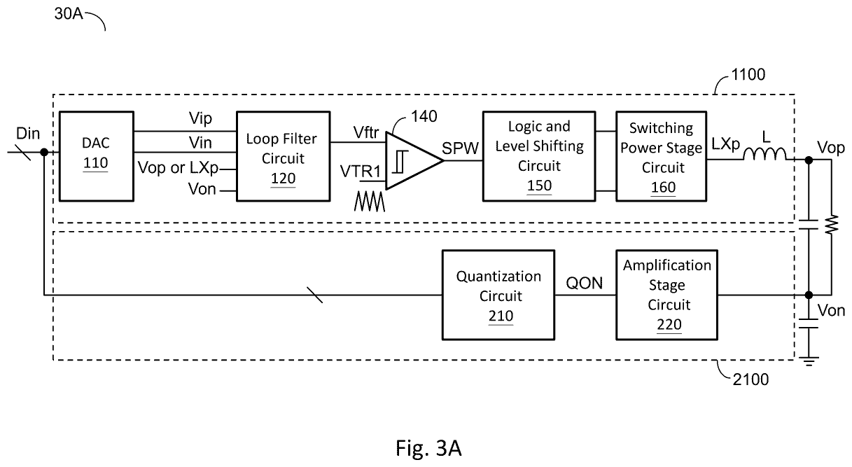

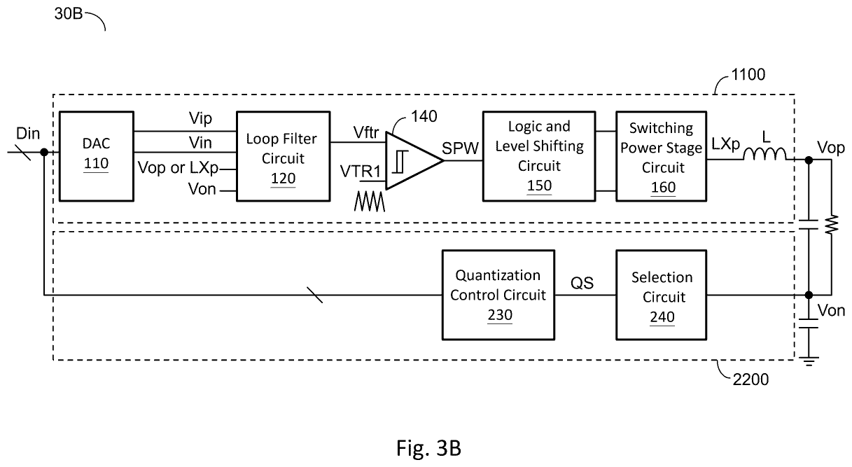

FIG. 3A and FIG. 3B show circuit block diagrams of the hybrid differential amplifier corresponding to FIG. 2A according to two embodiments of the present invention. In one embodiment, as shown in the hybrid differential amplifier 30A of FIG. 3A, a first amplifier 1100 includes a digital-to-analog converter 110, a loop filter circuit 120, a PWM circuit 140, a logic and level shifting circuit 150, and a switching power stage circuit 160. In one embodiment, the hybrid differential amplifier 30A is configured to generate a differential output signal Vod based on a digital input signal Din, wherein the digital-to-analog converter 110 is configured to convert the digital input signal Din into a first input signal Vip and a second input signal Vin in the analog domain. In one embodiment, the switching power stage circuit 160 and an inductor L are coupled to a switching node, at which a switching node signal LXp is generated.

In one embodiment, the loop filter circuit 120 is configured to perform linear integration based on a difference between the differential output signal Vod and the differential input signal Vid to generate a loop filter signal Vftr. In this embodiment, the differential output signal Vod refers to a difference signal between the first output signal Vop and the second output signal Von, or a difference signal between the switching node signal LXp and the second output signal Von. In one embodiment, the PWM circuit 140 is configured to generate a PWM output signal SPW based on a comparison between the loop filter signal Vftr and a triangular wave VTR1. In one embodiment, the PWM circuit 140 may be implemented as a comparator. The logic and level shifting circuit 150 is configured to generate a drive signal based on the PWM output signal SPW and shift the voltage level of the drive signal to a required drive level for the switching power stage circuit 160. The switching power stage circuit 160 is configured to switch the inductor L based on the drive signal generated by the logic and level shifting circuit 150 to generate the first output signal Vop. In this embodiment, the first amplifier 1100 performs feedback control such that the first output signal Vop includes a superposition of the first input signal Vip and the staircase wave.

In one embodiment, as shown in FIG. 3A, a second amplifier 2100 includes a quantization circuit 210 and an amplification stage circuit 220. In this embodiment, the quantization processing operation includes: the quantization circuit 210 is configured to generate a quantized output signal QON based on the digital input signal Din, and the amplification stage circuit 220 is configured to linearly amplify the quantized output signal QON to generate the second output signal Von, which will be described in detail later.

In another embodiment, as shown in FIG. 3B, a second amplifier 2200 includes a quantization control circuit 230 and a selection circuit 240. In this embodiment, the quantization control circuit 230 is coupled to the digital input signal Din, and the selection circuit 240 is coupled between the quantization control circuit 230 and the second output signal Von. In one embodiment, the quantization processing operation includes: the quantization control circuit 230 is configured to generate a quantization control signal QS based on the digital input signal Din, and the selection circuit 240 is configured to generate the second output signal Von based on the quantization control signal QS, which will be described in detail later. It should be noted that other details of the hybrid differential amplifier 30B in FIG. 3B can be referred to the description of FIG. 3A.

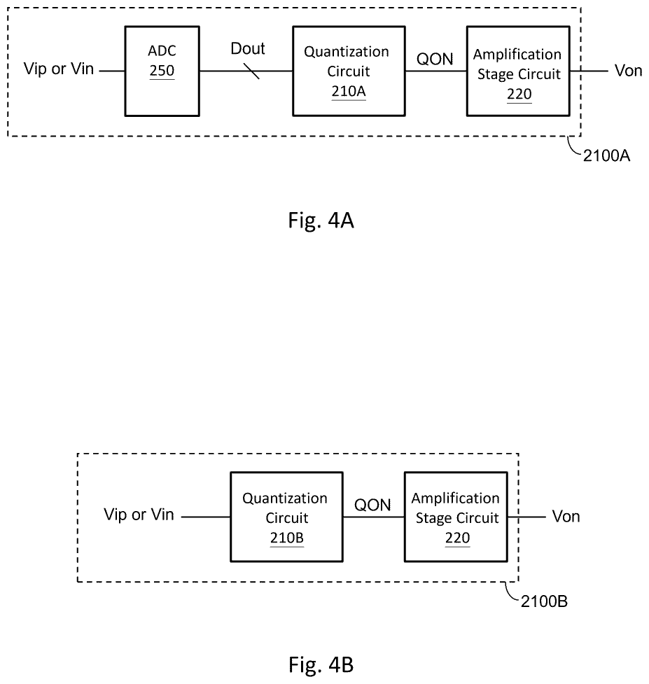

FIG. 4A and FIG. 4B show circuit block diagrams of the second amplifier corresponding to the hybrid differential amplifier shown in FIG. 3A according to two embodiments of the present invention. The second amplifiers shown in FIG. 4A and FIG. 4B are similar to the second amplifier 2100 of FIG. 3A. In one embodiment, as shown in FIG. 4A, the second amplifier 2100A further includes an analog-to-digital converter 250. The analog-to-digital converter 250 is configured to convert the first input signal Vip or the second input signal Vin to generate a digital output signal Dout. In this embodiment, a quantization circuit 210A of the second amplifier 2100A performs a quantization processing operation in a digital domain to generate a quantized output signal QON. In another embodiment, as shown in FIG. 4B, a quantization circuit 210B of the second amplifier 2100B is configured to generate the quantized output signal QON based on the first input signal Vip or the second input signal Vin in an analog domain. For additional details regarding the operation of FIG. 4A and FIG. 4B, please refer to the description of FIG. 3A.

It should be noted that the second amplifier 2200 of FIG. 3B may alternatively be configured as the second amplifier 2100A or 2100B shown in FIG. 4A or FIG. 4B.

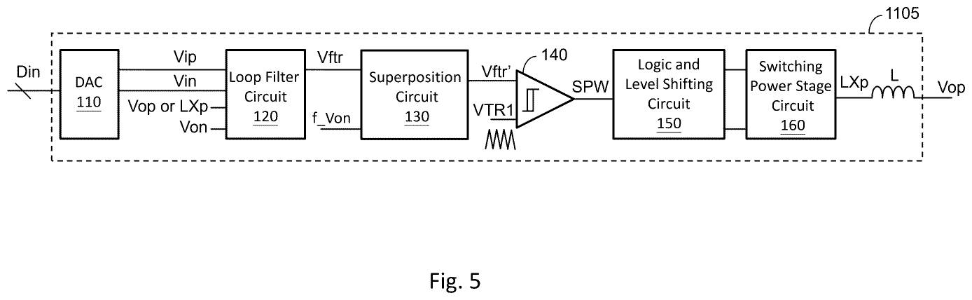

FIG. 5 shows a circuit block diagram of the first amplifier corresponding to the hybrid differential amplifier shown in FIG. 2A according to an embodiment of the present invention. In one embodiment, as shown in FIG. 5, a first amplifier 1105 further includes a superposition circuit 130, which is configured to generate a processed loop filter signal Vftr′ based on a superposition of a loop filter signal Vftr and a related signal f_Von associated with the second output signal Von. For other operational details of the first amplifier 1105, please refer to the description of FIG. 3A. It should be noted that the first amplifiers of FIG. 3A and FIG. 3B may be configured as the first amplifier 1105 of FIG. 5.

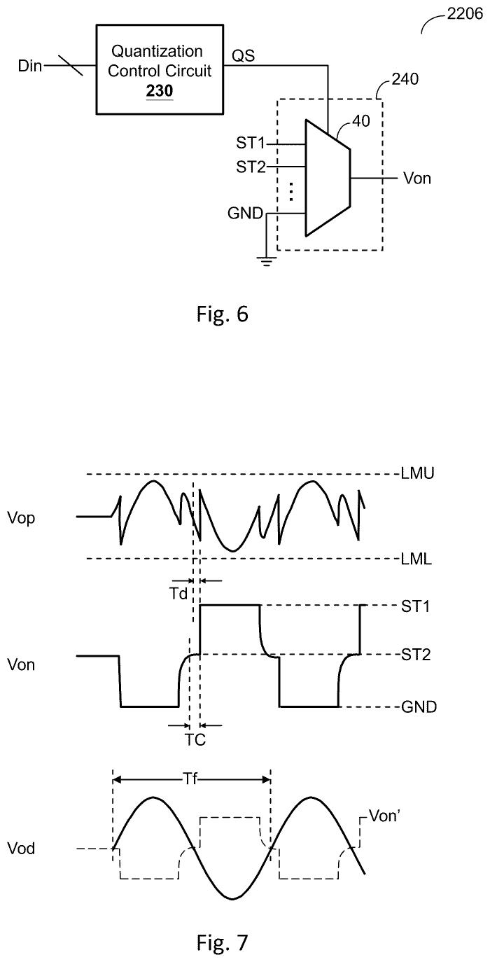

FIG. 6 shows a schematic circuit diagram of the second amplifier corresponding to the hybrid differential amplifier of FIG. 3B according to an embodiment of the present invention. The second amplifier 2206 in FIG. 6 is one embodiment of the second amplifier 2200 shown in FIG. 3B. As shown in FIG. 6, in one embodiment, the selection circuit 240 includes a multiplexer 40. In this embodiment, the aforementioned quantization processing operation includes: the quantization control circuit 230 configured to generate a quantization control signal QS based on a digital input signal Din (or the second input signal Vin) and at least one quantization threshold level; and the selection circuit 240 (i.e., the multiplexer 40) configured to select a first staircase level ST1, a second staircase level ST2, or a ground level GND based on the quantization control signal QS to generate the second output signal Von.

Please refer to both FIG. 6 and FIG. 7. FIG. 7 shows a waveform diagram of the hybrid differential amplifier according to an embodiment of the present invention. In one embodiment, based on the configuration shown in FIG. 6, the second output signal Von may include a staircase wave related to the fundamental frequency Ff, and the staircase wave includes at least three quantized output levels. As shown in the waveform of the second output signal Von in FIG. 7, in one embodiment, the at least three quantized output levels include a first staircase level ST1, a second staircase level ST2, and a ground level GND. In this embodiment, the second staircase level ST2 is lower than the first staircase level ST1 and higher than the ground level GND. In one embodiment, a duration TC of the second staircase level ST2 is longer than a delay time Td between the first output signal Vop and the second output signal Von, such that the distortion level of the differential output signal Vod is less than a predetermined level.

As shown in FIG. 6 and FIG. 7, in a specific embodiment, the at least one quantization threshold level includes a lower quantization threshold level and a higher quantization threshold level. When the digital input signal Din is lower than the lower quantization threshold level, the selection circuit 240 selects the ground level GND to generate the second output signal Von based on the quantization control signal QS. When the digital input signal Din is higher than the lower quantization threshold level and lower than the higher quantization threshold level, the selection circuit 240 selects the second staircase level ST2 to generate the second output signal Von based on the quantization control signal QS. When the digital input signal Din is higher than the higher quantization threshold level, the selection circuit 240 selects the first staircase level ST1 to generate the second output signal Von based on the quantization control signal QS. In the above specific embodiment, the second output signal Von is a staircase wave with three quantized output levels. In other embodiments, when the at least one quantization threshold level includes three or more quantization threshold levels, the at least three quantized output levels may include four or more quantized output levels, and the present invention may be extended accordingly.

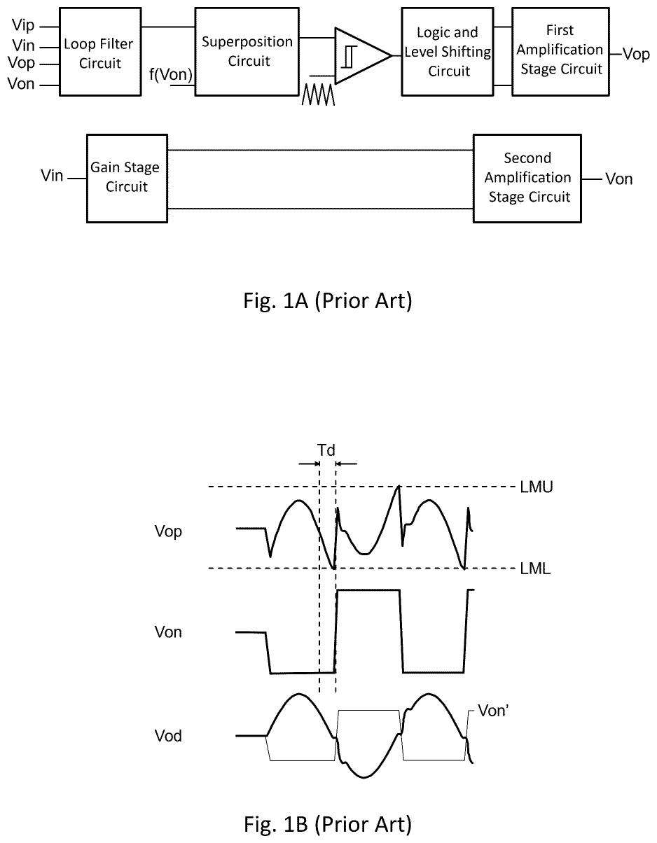

It should be noted that the fundamental frequency Ff corresponds to the reciprocal of a period Tf of the differential output signal Vod. It should be further noted that, compared to the prior art waveform diagram shown in FIG. 1B, the present invention utilizes quantization processing operation such that the second output signal Von is a staircase wave with at least three levels, and a duration TC of the second staircase level ST2 is longer than the delay time Td. As a result, a zero-crossing point of the differential output signal Vod (solid line of the third waveform in FIG. 7) overlaps with the duration TC of the second staircase level ST2 (dashed line in the third waveform of FIG. 7), such that the first output signal Vop can remain between a lower limit LML and an upper limit LMU of a supply voltage. From one specific perspective, the duration TC of the second staircase level ST2 provides a safeguard or a time window which can absorb any delay-induced discrepancies between Vop and Von, thus preventing any signal along the signal path of the hybrid differential amplifier to drift into the non-linear regions (i.e., beyond LML or LMU). In other words, the signal Vop will not saturate, but rather be clamped to the lower limit LML or the upper limit LMU, thereby reducing the distortion level of the first output signal Vop and the differential output signal Vod. That is, the first output signal Vop and the differential output signal Vod achieve improved linearity. By properly selecting the duration TC, the distortion level can meet a predetermined requirement, for example, being lower than a predetermined level. In FIG. 7, the dashed waveform of the second output signal Von′ is the waveform of the second output signal Von in the same time domain as the differential output signal Vod. The aforementioned zero-crossing point refers to the crossing point of the differential output signal Vod with its common-mode level.

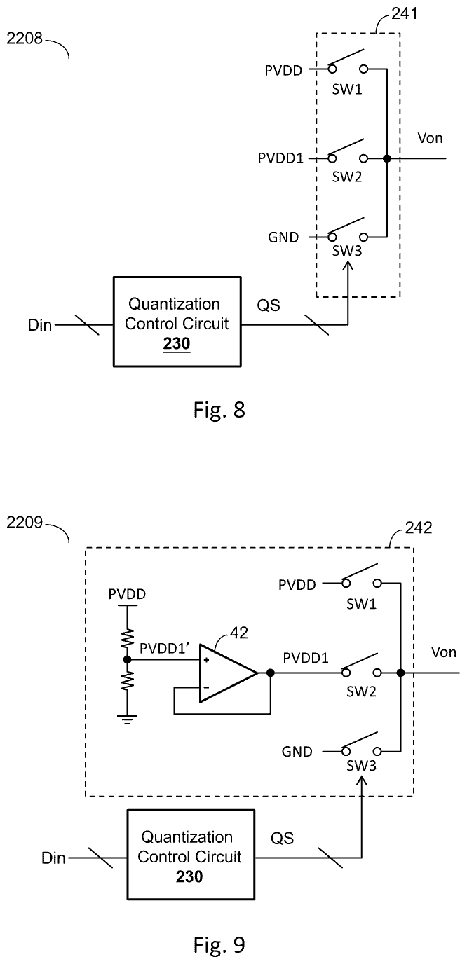

FIG. 8 to FIG. 11 show schematic circuit diagrams of a second amplifier corresponding to the hybrid differential amplifier shown in FIG. 6 according to plural embodiments of the present invention. The second amplifiers 2208 to 2211 in FIG. 8 to FIG. 11 are specific embodiments of the second amplifier 2206 shown in FIG. 6. As shown in FIG. 8 to FIG. 11, a first staircase level ST1 corresponds to a voltage level of a supply voltage PVDD, and a second staircase level ST2 corresponds to a voltage level of a divided voltage of the supply voltage PVDD. The operational details of the selection circuits 241 to 244 shown in FIG. 8 to FIG. 11 are described below.

In one embodiment, as shown in FIG. 8, the selection circuit 241 includes switches SW1 to SW3, configured to select the supply voltage PVDD, another supply voltage PVDD1 (its level can be a division of PVDD), or a ground level GND based on a quantization control signal QS to generate a second output signal Von.

The second amplifier 2209 in FIG. 9 is similar to the second amplifier 2208 in FIG. 8. In one embodiment, the selection circuit 242 in FIG. 9 further includes a buffer 42, configured to linearly amplify a divided voltage PVDD1′ of the supply voltage PVDD to generate the other supply voltage PVDD1.

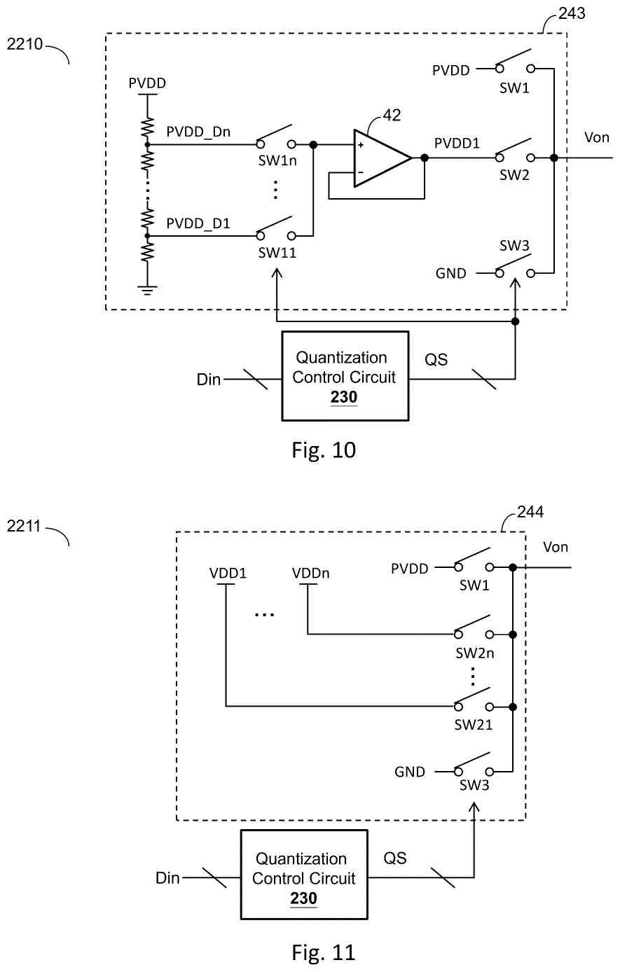

The second amplifier 2210 in FIG. 10 is similar to the second amplifier 2209 in FIG. 9. In one embodiment, the selection circuit 243 in FIG. 10 further includes n switches SW11 to SW1n. One end of each of the switches SW11 to SW1n is coupled to corresponding one of n divided voltages PVDD_D1 to PVDD_Dn of the supply voltage PVDD, and the other ends are commonly coupled to the positive input terminal of the buffer 42, where n is a positive integer. In one embodiment, the switches SW11 to SW1n are configured to select one of the divided voltages PVDD_D1 to PVDD_Dn based on the quantization control signal QS and input it to the buffer 42 to generate the other supply voltage PVDD1. In this embodiment, the second output signal Von generated by the selection circuit 243 is a staircase wave including more than three quantized output levels.

In one embodiment, as shown in FIG. 11, the selection circuit 244 includes switches SW1 and SW3 and plural switches SW21 to SW2n. In this embodiment, the plural switches SW21 to SW2n are respectively coupled to plural system voltages VDD1 to VDDn. In one embodiment, the switches SW1, SW21 to SW2n, and SW3 are configured to select at least one of the supply voltage PVDD, the plural system voltages VDD1 to VDDn, or the ground level GND based on the quantization control signal QS to generate the second output signal Von. In this embodiment, the second output signal Von generated by the selection circuit 244 is also a staircase wave including more than three quantized output levels.

It should be noted that in the embodiments of FIGS. 10 and 11, by generating the second output signal Von as a multi-level staircase wave (including more than three quantized output levels), the zero-crossing point of the differential output signal Vod can intersect with more than two quantized output levels (staircase levels), so that the first output signal Vop remains between the lower limit LML and upper limit LMU of the supply voltage and does not saturate, thereby reducing the distortion level of the first output signal Vop and the differential output signal Vod. It should be further noted that such saturation may also occur at other nodes in the signal path. According to the present invention, these saturation phenomena occurring in the prior art can be effectively avoided, thereby effectively reducing the distortion level of the first output signal Vop and the differential output signal Vod.

FIG. 12A and FIG. 12B show schematic circuit diagrams of the second amplifier of the hybrid differential amplifier according to two embodiments of the present invention. As shown in FIG. 12A, in one embodiment, the second amplifier 2112A is configured as a linear amplifier operating in the continuous time domain. In this embodiment, the second amplifier 2112A includes a quantization circuit 211 and an amplification stage circuit 221. The quantization circuit 211 is coupled to the first input signal Vip or the second input signal Vin, and the amplification stage circuit 221 is coupled between the quantization circuit 211 and the second output signal Von. In one embodiment, the quantization processing operation includes: the quantization circuit 211 being configured to generate a quantized output signal QO1 based on the second input signal Vin and at least one quantization threshold level; and the amplification stage circuit 221 being configured to linearly amplify the quantized output signal QO1 to generate the second output signal Von.

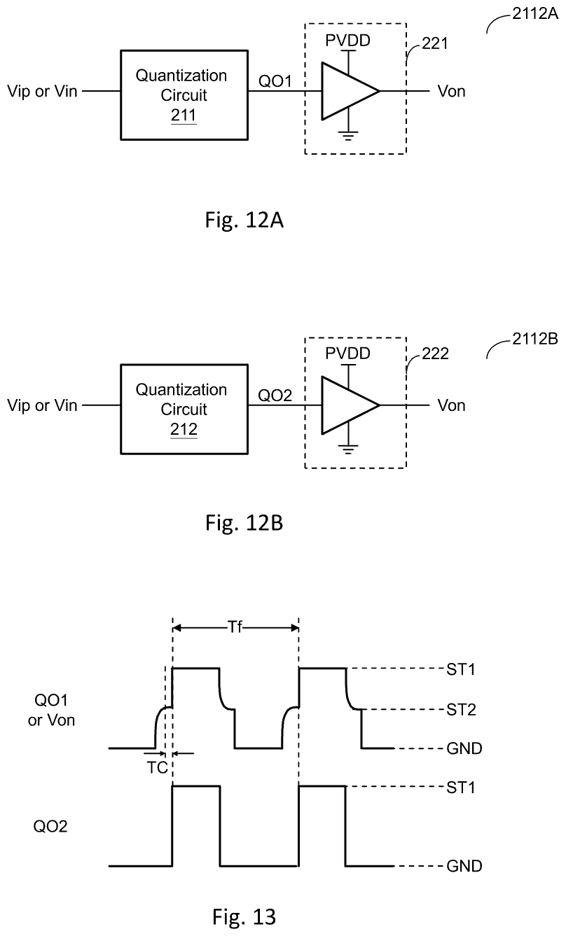

Please refer to FIGS. 12A and 13. FIG. 13 shows a waveform diagram of quantized output signals corresponding to FIGS. 12A and 12B according to two embodiments of the present invention. In the embodiment shown in FIG. 12A, the quantized output signal QO1 is a staircase wave related to the fundamental frequency Ff. The staircase wave includes three levels respectively corresponding to a first staircase level ST1, a second staircase level ST2, and a ground level GND.

Please refer to FIGS. 12B and 13. The second amplifier 2112B of FIG. 12B is similar to the second amplifier 2112A of FIG. 12A. The difference lies in that the quantized output signal QO2 generated by the quantization circuit 212 of FIG. 12B is a square wave related to the fundamental frequency Ff. The square wave includes two levels corresponding to the first staircase level ST1 and the ground level GND. For other details of FIG. 12B, please refer to the description of FIG. 12A.

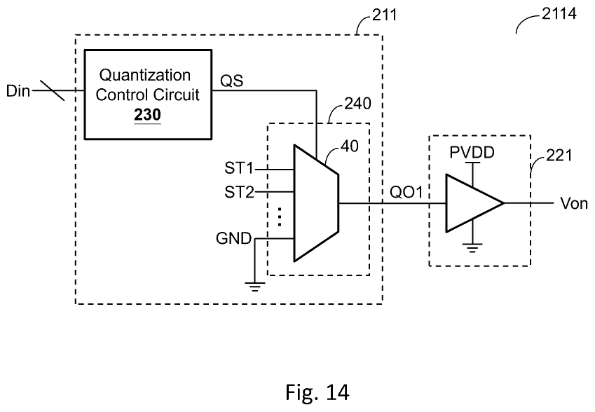

FIG. 14 shows a schematic circuit diagram of the second amplifier corresponding to the hybrid differential amplifier of FIG. 12A according to an embodiment of the present invention. The hybrid differential amplifier 2114 of FIG. 14 is a specific embodiment of the hybrid differential amplifier 2112A of FIG. 12A. In one embodiment, the quantization circuit 211 includes a quantization control circuit 230 and a selection circuit 240. In this embodiment, the quantization processing operation includes: the selection circuit 240 generates the quantized output signal QO1, which is then linearly amplified by the amplification stage circuit 221 to generate the second output signal Von. For other operational details of the quantization control circuit 230 and the selection circuit 240, please refer to the description of FIG. 6.

It should be noted that in other embodiments, the selection circuit 240 in FIG. 14 may also be configured as the selection circuits 241 to 244 shown in FIG. 8 to FIG. 11, as would be understood by those skilled in the art.

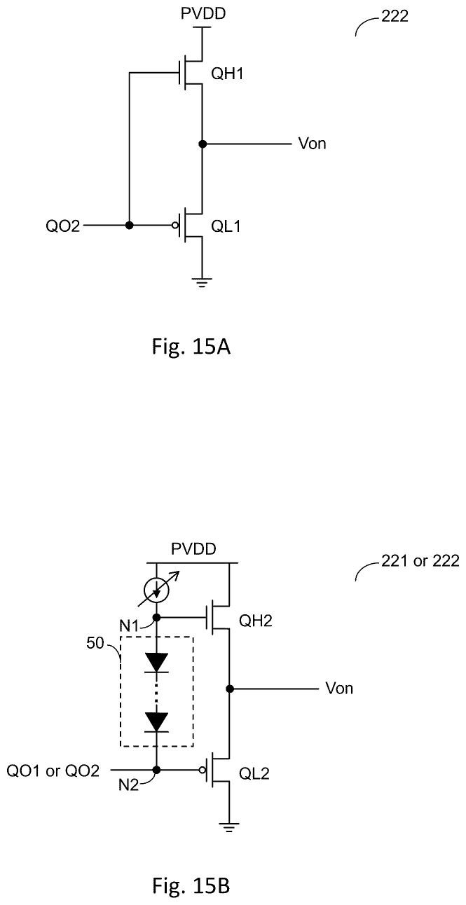

FIG. 15A shows a schematic diagram of an amplification stage circuit corresponding to the second amplifier of FIG. 12B according to a specific embodiment of the present invention. In one specific embodiment, the amplification stage circuit 222 of FIG. 12B may be configured as the amplification stage circuit shown in FIG. 15A. As shown in FIG. 15A, the amplification stage circuit 222 is configured as a class-B amplifier, including a first high-side transistor QH1 and a first low-side transistor QL1. The gate of the first high-side transistor QH1 is coupled to the gate of the first low-side transistor QL1, and both are further coupled to the quantization circuit 212. The first high-side transistor QH1 and the first low-side transistor QL1 are connected in series between the supply voltage PVDD and ground to generate the second output signal Von. In one embodiment, the first high-side transistor QH1 is an NMOS transistor and he first low-side transistor QL1 is a PMOS transistor. In this embodiment, since the quantized output signal QO2 has square-wave characteristics and is linearly amplified by the amplification stage circuit 222 configured as a class-B amplifier, the inherent crossover distortion of the class-B amplifier causes a transitional region near the zero-crossing point of the output waveform. As a result, although the quantized output signal QO2 itself is a square wave, the second output signal Von generated by such linear amplification exhibits a staircase waveform with an intermediate level, thereby inherently possessing staircase-wave characteristics. In one embodiment, the waveform of the second output signal Von in FIG. 12B or FIG. 15A corresponds to the first waveform in FIG. 13, which is a staircase wave including a first staircase level ST1, a second staircase level ST2, and a ground level GND. In the embodiment of FIG. 15A, the duration TC of the second staircase level ST2 is related to the turn-on thresholds of the first high-side transistor QH1 and the first low-side transistor QL1. In this embodiment, the supply voltage PVDD has the first staircase level ST1, and the ground potential corresponds to the ground level GND.

FIG. 15B shows a schematic diagram of an amplification stage circuit corresponding to the second amplifiers of FIGS. 12A and 12B according to a specific embodiment of the present invention. In one specific embodiment, the amplification stage circuits 221 and 222 of FIGS. 12A and 12B, respectively, may be configured as the amplification stage circuit shown in FIG. 15B. As shown in FIG. 15B, the amplification stage circuit 221 or 222 is configured as a class-AB amplifier, including a second high-side transistor QH2, a second low-side transistor QL2, and a level shifter 50. In one embodiment, the second high-side transistor QH2 is an NMOS transistor and the second low-side transistor QL2 is a PMOS transistor. In one embodiment, a first terminal N1 and a second terminal N2 of the level shifter 50 are respectively coupled to the gates of the second high-side transistor QH2 and the second low-side transistor QL2, and the level shifter 50 is configured to maintain a voltage difference therebetween. The input terminal (e.g., the second terminal N2 in this embodiment) is coupled to the quantized output signals QO1 or QO2 to control the voltages on the first terminal N1 and the second terminal N2. In one embodiment, the second high-side transistor QH2 and the second low-side transistor QL2 are connected in series to generate the second output signal Von. In one embodiment, the waveform of the second output signal Von in FIG. 15B corresponds to the first waveform in FIG. 13, i.e., a staircase wave including the first staircase level ST1, the second staircase level ST2, and the ground level GND. In this embodiment, the duration TC of the second staircase level ST2 is related to the turn-on thresholds of the second high-side transistor QH2 and the second low-side transistor QL2, and the offset level of the level shifter 50. Specifically, when the offset level is less than the sum of the absolute values of the turn-on thresholds of the second high-side transistor QH2 and the second low-side transistor QL2, the amplification stage circuit 221 or 222 exhibits similar characteristics to the class-B amplifier. By adjusting the offset level, the duration TC of the second staircase level ST2 can be adjusted. In this regard, the level shifter provides a degree of freedom that allows the class-AB amplifier to behave like either a highly linear amplifier or a distortion-prone amplifier, depending on the selected offset level. In this embodiment, the supply voltage PVDD has the first staircase level ST1, and the ground potential corresponds to the ground level GND.

It should be noted that since the quantized output signal QO1 generated by the quantization circuit 211 of FIG. 12A is a staircase wave with at least three quantized output levels, the amplification stage circuit 221 must be a high-linearity amplifier. This is because the amplifier is required to faithfully preserve all three distinct levels of the input signal without introducing transitional distortion. Therefore, the amplification stage circuit 221 is suitable to be configured as the high-linearity class-AB amplifier shown in FIG. 15B. In contrast, since the quantized output signal QO2 in FIG. 12B is a square wave, the amplification stage circuit 222 may utilize its inherent distortion characteristics to generate the second output signal Von with staircase waveform characteristics through linear amplification of the quantized output signal QO2. Thus, the amplification stage circuit 222 may be configured as the class-B amplifier or the class-AB amplifier shown in FIG. 15A or FIG. 15B, which has lower linearity.

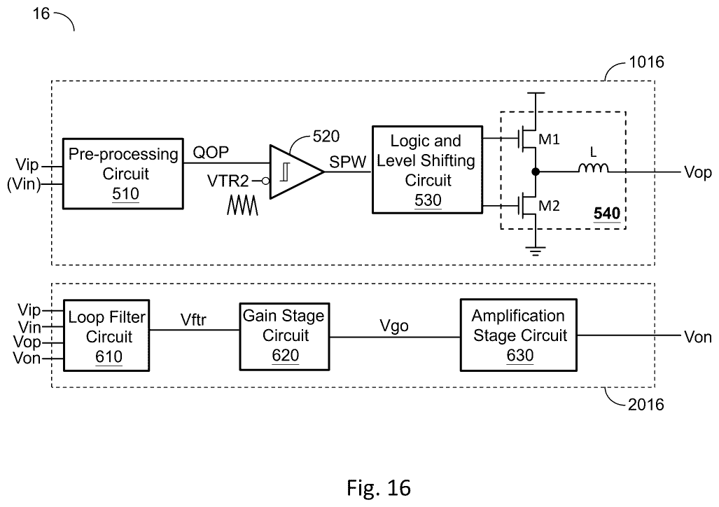

FIG. 16 shows a circuit block diagram of the hybrid differential amplifier corresponding to FIG. 2B according to an embodiment of the present invention. In one embodiment, as shown in the hybrid differential amplifier 16 of FIG. 16, a first amplifier 1016 includes: a pre-processing circuit 510, a PWM circuit 520, a logic and level shifting circuit 530, and a switching power stage circuit 540. In one embodiment, the pre-processing circuit 510 generates a pre-processed output signal QOP based on the first input signal Vip and/or the second input signal Vin. The pre-processing operations will be detailed later. The PWM circuit 520 generates a PWM output signal SPW based on the comparison between the pre-processed output signal QOP and a triangular wave VTR2. The switching power stage circuit 540 includes a high-side transistor M1 and a low-side transistor M2 for switching an inductor L based on the PWM output signal SPW to generate the first output signal Vop.

In one embodiment, as shown in FIG. 16, the second amplifier 2016 includes: a loop filter circuit 610, a gain stage circuit 620, and an amplification stage circuit 630. The loop filter circuit 610 linearly integrates the difference between the differential output signal Vod and the differential input signal Vid to generate a loop filter signal Vftr. The gain stage circuit 620 linearly amplifies the loop filter signal Vftr to generate a gain output signal Vgo. The amplification stage circuit 630 linearly amplifies the gain output signal Vgo to generate the second output signal Von. In this embodiment, the second amplifier 2016 performs feedback control such that the second output signal Von includes a staircase wave related to the fundamental frequency Ff (see the earlier descriptions on the staircase wave).

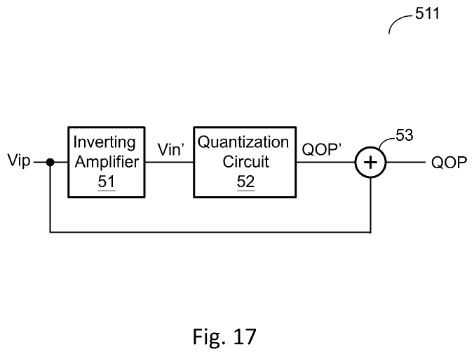

FIG. 17 shows a circuit block diagram of a pre-processing circuit corresponding to the first amplifier of FIG. 16 according to one embodiment of the present invention. In one embodiment, the pre-processing circuit 510 of FIG. 16 is configured as the pre-processing circuit 511 shown in FIG. 17. In one embodiment, the pre-processing circuit 511 includes an inverting amplifier 51, a quantization circuit 52, and an adder 53. In the embodiment of FIG. 17, the pre-processing operation includes: inverting the first input signal Vip by the inverting amplifier 51 to generate an inverted signal Vin′, which is in-phase with the second input signal Vin; the quantization circuit 52 performs the aforementioned quantization processing operation on the inverted signal Vin′ based on at least one quantization threshold level to generate a quantized output signal QOP′; and the adder 53 superimposes the quantized output signal QOP′ and the first input signal Vip to generate the pre-processed output signal QOP. In this embodiment, the quantized output signal QOP′ includes a staircase wave with three levels: the first staircase level ST1, the second staircase level ST2, and the ground level GND. It should be noted that the quantization circuit 52 may be configured as the quantization circuit 211 shown in FIG. 14, as would be understood by those skilled in the art.

The present invention has been described in considerable detail with reference to certain preferred embodiments thereof. It should be understood that the description is for illustrative purpose, not for limiting the broadest scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, to perform an action “according to” a certain signal as described in the context of the present invention is not limited to performing an action strictly according to the signal itself, but can be performing an action according to a converted form or a scaled-up or down form of the signal, i.e., the signal can be processed by a voltage-to-current conversion, a current-to-voltage conversion, and/or a ratio conversion, etc. before an action is performed. It is not limited for each of the embodiments described hereinbefore to be used alone; under the spirit of the present invention, two or more of the embodiments described hereinbefore can be used in combination. For example, two or more of the embodiments can be used together, or, a part of one embodiment can be used to replace a corresponding part of another embodiment. In view of the foregoing, the spirit of the present invention should cover all such and other modifications and variations, which should be interpreted to fall within the scope of the following claims and their equivalents.

What is claimed is:

1. A hybrid differential amplifier, configured to generate a differential output signal based on a differential input signal for driving a load, wherein the differential input signal has a fundamental frequency, the hybrid differential amplifier comprising:
a first amplifier, configured as an inductive switching converter and configured to perform pulse width modulation (PWM) conversion based on a first input signal of the differential input signal to switch an inductor and generate a first output signal of the differential output signal; and
a second amplifier, configured to generate a second output signal of the differential output signal based on a second input signal of the differential input signal; wherein the second amplifier is configured as another type of amplifier different from the inductive switching converter; wherein one of the first amplifier or the second amplifier is further configured to generate the first output signal or the second output signal based on feedback from the differential output signal, such that the differential output signal is linearly related to the differential input signal; wherein the other one of the first amplifier or the second amplifier is further configured to perform a quantization processing operation on the first input signal or the second input signal, such that the second output signal includes a staircase wave related to the fundamental frequency, wherein the staircase wave includes at least three quantized output levels; wherein the quantization processing operation includes: generating a quantized output signal based on the first input signal or the second input signal and at least one quantization threshold level, such that the second output signal includes the staircase wave.

2. The hybrid differential amplifier of claim 1, wherein the at least three quantized output levels include a first staircase level, a second staircase level, and a ground level, wherein the second staircase level is lower than the first staircase level and higher than the ground level, and a duration of the second staircase level is longer than a delay time between the first output signal and the second output signal, such that a distortion level of the differential output signal is less than a predetermined level.

3. The hybrid differential amplifier of claim 2, wherein the first staircase level corresponds to a voltage level of a supply voltage, and the second staircase level corresponds to a divided voltage level of the supply voltage.

4. The hybrid differential amplifier of claim 2, wherein the second amplifier includes:
a quantization control circuit, coupled to the second input signal; and
a selection circuit, coupled between the quantization control circuit and the second output signal;
wherein the quantization processing operation includes:
the quantization control circuit being configured to generate a quantization control signal based on the second input signal and the at least one quantization threshold level; and
the selection circuit being configured to select the first staircase level, the second staircase level, or the ground level based on the quantization control signal to generate the quantized output signal;
wherein the quantized output signal corresponds to the second output signal.

5. The hybrid differential amplifier of claim 4, wherein the first amplifier includes:
a loop filter circuit, configured to perform linear integration based on a difference between the differential output signal and the differential input signal to generate a loop filter signal;
a PWM circuit, configured to generate a PWM output signal based on a comparison of the loop filter signal and a triangular wave; and
a switching power stage circuit, configured to switch the inductor based on the PWM output signal to generate the first output signal;
wherein the first amplifier is configured to perform feedback control such that the first output signal includes a superposition of the first input signal and the staircase wave.

6. The hybrid differential amplifier of claim 2, wherein the second amplifier is configured as a linear amplifier operating in continuous time domain, and includes:
a quantization circuit, coupled to the second input signal; and
an amplification stage circuit, coupled between the quantization circuit and the second output signal;
wherein the quantization processing operation includes:
the quantization circuit being configured to generate the quantized output signal based on the second input signal and the at least one quantization threshold level, wherein the quantized output signal includes a square wave or the staircase wave, each of which are related to the fundamental frequency; and
the amplification stage circuit being configured to linearly amplify the quantized output signal to generate the second output signal;
wherein the square wave includes two levels corresponding to the first staircase level and the ground level, and the staircase wave includes three levels corresponding to the first staircase level, the second staircase level, and the ground level.

7. The hybrid differential amplifier of claim 6, wherein the first amplifier includes:
a loop filter circuit, configured to perform linear integration based on a difference between the differential output signal and the differential input signal to generate a loop filter signal;
a PWM circuit, configured to generate a PWM output signal based on a comparison of the loop filter signal and a triangular wave; and
a switching power stage circuit, configured to switch the inductor based on the PWM output signal to generate the first output signal;
wherein the first amplifier performs feedback control such that the first output signal includes a superposition of the first input signal and the staircase wave.

8. The hybrid differential amplifier of claim 6, wherein when the quantized output signal includes the square wave related to the fundamental frequency, the amplification stage circuit includes:
a class-B amplifier including a first high-side transistor and a first low-side transistor, wherein a gate of the first high-side transistor and a gate of the first low-side transistor are coupled to each other and are coupled to the quantized output signal, and the first high-side transistor and the first low-side transistor are connected in series between a supply voltage and a ground potential to generate the second output signal, wherein the duration of the second staircase level is related to a turn-on threshold of the first high-side transistor and a turn-on threshold of the first low-side transistor; or
a class-AB amplifier including a second high-side transistor, a second low-side transistor, and a level shifter, wherein a first terminal and a second terminal of the level shifter are respectively coupled to a gate of the second high-side transistor and a gate of the second low-side transistor, to maintain a voltage difference between the gates of the second high-side transistor and the second low-side transistor, and an input terminal of the level shifter is coupled to the quantized output signal to control voltages of the first terminal and the second terminal, wherein the second high-side transistor and the second low-side transistor are connected in series between a supply voltage and a ground potential to generate the second output signal, wherein a duration of the second staircase level is related to a turn-on threshold of the second high-side transistor, a turn-on threshold of the second low-side transistor, and an offset level of the level shifter;
wherein the supply voltage has the first staircase level, and the ground potential corresponds to the ground level, wherein the offset level is positively correlated with the voltage difference.

9. The hybrid differential amplifier of claim 6, wherein when the quantized output signal includes the staircase wave related to the fundamental frequency, the amplification stage circuit includes:
a class-AB amplifier including a high-side transistor, a low-side transistor, and a level shifter, wherein a first terminal and a second terminal of the level shifter are respectively coupled to a gate of the high-side transistor and a gate of the low-side transistor, to maintain a voltage difference between the gates of the high-side transistor and the low-side transistor, and an input terminal of the level shifter is coupled to the quantized output signal to control voltages of the first terminal and the second terminal, wherein the high-side transistor and the low-side transistor are connected in series between a supply voltage and a ground potential to generate the second output signal, wherein a duration of the second staircase level is related to a turn-on threshold of the high-side transistor, a turn-on threshold of the low-side transistor, and an offset level of the level shifter;
wherein the supply voltage has the first staircase level, and the ground potential corresponds to the ground level, wherein the offset level is positively correlated with the voltage difference.

10. The hybrid differential amplifier of claim 2, wherein the first amplifier includes:
a pre-processing circuit, configured to perform a pre-processing operation based on the first input signal and/or the second input signal to generate a pre-processed output signal;
a PWM circuit, configured to generate a PWM output signal based on a comparison of the pre-processed output signal and a triangular wave; and
a switching power stage circuit, configured to switch the inductor based on the PWM output signal to generate the first output signal;
wherein the pre-processing operation includes: performing the quantization processing operation based on the first input signal and/or the second input signal and the at least one quantization threshold level to generate the quantized output signal, and superimposing the quantized output signal with the first input signal to generate the pre-processed output signal;
wherein the quantized output signal includes the staircase wave, and the staircase wave includes the first staircase level, the second staircase level, and the ground level.

11. The hybrid differential amplifier of claim 10, wherein the second amplifier includes:
a loop filter circuit, configured to perform linear integration based on a difference between the differential output signal and the differential input signal to generate a loop filter signal;
a gain stage circuit, configured to linearly amplify the loop filter signal to generate a gain output signal; and
an amplification stage circuit, configured to linearly amplify the gain output signal to generate the second output signal;
wherein the second amplifier performs feedback control such that the second output signal includes the staircase wave.

12. A hybrid differential amplification method, configured to generate a differential output signal based on a differential input signal for driving a load, wherein the differential input signal has a fundamental frequency, the hybrid differential amplification method comprising:
performing pulse width modulation (PWM) conversion based on a first input signal of the differential input signal to generate a first output signal of the differential output signal; and
generating a second output signal of the differential output signal based on a second input signal of the differential input signal;
wherein the second output signal is generated in a manner different from the PWM conversion;
wherein one of the first output signal or the second output signal is further generated based on feedback from the differential output signal, such that the differential output signal is linearly related to the differential input signal;
wherein the other one of the first output signal or the second output signal is further generated based on a quantization processing operation of the first input signal or the second input signal, such that the second output signal includes a staircase wave related to the fundamental frequency, wherein the staircase wave includes at least three quantized output levels;
wherein the quantization processing operation includes: generating a quantized output signal based on the first input signal or the second input signal and at least one quantization threshold level, such that the second output signal includes the staircase wave.

13. The hybrid differential amplification method of claim 12, wherein the at least three quantized output levels include a first staircase level, a second staircase level, and a ground level, wherein the second staircase level is lower than the first staircase level and higher than the ground level, and a duration of the second staircase level is longer than a delay time between the first output signal and the second output signal, such that a distortion level of the differential output signal is less than a predetermined level.

14. The hybrid differential amplification method of claim 13, wherein the first staircase level corresponds to a voltage level of a supply voltage, and the second staircase level corresponds to a divided voltage level of the supply voltage.

15. The hybrid differential amplification method of claim 13, wherein the quantization processing operation includes:
generating a quantization control signal based on the second input signal and the at least one quantization threshold level; and
selecting the first staircase level, the second staircase level, or the ground level based on the quantization control signal to generate the quantized output signal;
wherein the quantized output signal corresponds to the second output signal.

16. The hybrid differential amplification method of claim 15, wherein the step of generating the first output signal includes:
performing linear integration based on a difference between the differential output signal and the differential input signal to generate a loop filter signal;
generating a PWM output signal based on a comparison of the loop filter signal and a triangular wave; and
switching based on the PWM output signal to generate the first output signal;
wherein the step of generating the first output signal includes: performing feedback control such that the first output signal includes a superposition of the first input signal and the staircase wave.

17. The hybrid differential amplification method of claim 13, wherein the quantization processing operation includes:
generating the quantized output signal based on the second input signal and the at least one quantization threshold level, wherein the quantized output signal includes a square wave or the staircase wave, each of which are related to the fundamental frequency; and
linearly amplifying the quantized output signal to generate the second output signal;
wherein the square wave includes two levels corresponding to the first staircase level and the ground level, and the staircase wave includes three levels corresponding to the first staircase level, the second staircase level, and the ground level.

18. The hybrid differential amplification method of claim 17, wherein the step of generating the first output signal includes:
performing linear integration based on a difference between the differential output signal and the differential input signal to generate a loop filter signal;
generating a PWM output signal based on a comparison of the loop filter signal and a triangular wave; and
switching based on the PWM output signal to generate the first output signal;
wherein the step of generating the first output signal includes: performing feedback control such that the first output signal includes a superposition of the first input signal and the staircase wave.

19. The hybrid differential amplification method of claim 17, wherein when the quantized output signal includes the square wave related to the fundamental frequency, the step of linearly amplifying the quantized output signal includes:
performing class-B amplification to control conduction level of a first high-side transistor and a first low-side transistor to generate the second output signal, wherein the first high-side transistor and the first low-side transistor are connected in series between a supply voltage and a ground potential to generate the second output signal, and the duration of the second staircase level is related to a turn-on threshold of the first high-side transistor and a turn-on threshold of the first low-side transistor; or
performing class-AB amplification to maintain a voltage difference between a gate of a second high-side transistor and a gate of a second low-side transistor, and to control the voltage difference based on the quantized output signal to generate the second output signal, wherein the second high-side transistor and the second low-side transistor are connected in series between a supply voltage and a ground potential to generate the second output signal, and the duration of the second staircase level is related to a turn-on threshold of the second high-side transistor, a turn-on threshold of the second low-side transistor, and an offset level, wherein the offset level is positively correlated with the voltage difference; wherein the supply voltage has the first staircase level, and the ground potential corresponds to the ground level.

20. The hybrid differential amplification method of claim 17, wherein when the quantized output signal includes the staircase wave related to the fundamental frequency, the step of linearly amplifying the quantized output signal includes:
performing class-AB amplification to maintain a voltage difference between a gate of a high-side transistor and a gate of a low-side transistor, and to control the voltage difference based on the quantized output signal to generate the second output signal, wherein the high-side transistor and the low-side transistor are connected in series between a supply voltage and a ground potential to generate the second output signal, and the duration of the second staircase level is related to a turn-on threshold of the high-side transistor, a turn-on threshold of the low-side transistor, and an offset level, wherein the offset level is positively correlated with the voltage difference; wherein the supply voltage has the first staircase level, and the ground potential corresponds to the ground level.

21. The hybrid differential amplification method of claim 13, wherein the step of generating the first output signal includes:
performing a pre-processing operation based on the first input signal and/or the second input signal to generate a pre-processed output signal;
generating a PWM output signal based on a comparison of the pre-processed output signal and a triangular wave; and
switching based on the PWM output signal to generate the first output signal;
wherein the pre-processing operation includes:
performing the quantization processing operation based on the first input signal and/or the second input signal and the at least one quantization threshold level to generate the quantized output signal, and
superimposing the quantized output signal with the first input signal to generate the pre-processed output signal;
wherein the quantized output signal includes the staircase wave, and the staircase wave includes the first staircase level, the second staircase level, and the ground level.

22. The hybrid differential amplification method of claim 21, wherein the step of generating the second output signal includes:
performing linear integration based on a difference between the differential output signal and the differential input signal to generate a loop filter signal;
linearly amplifying the loop filter signal to generate a gain output signal; and
linearly amplifying the gain output signal to generate the second output signal;
wherein the step of generating the second output signal includes: performing feedback control such that the second output signal includes the staircase wave.
